(19) United States
(12) Patent Application Publication
(10) Pub. No.: US 2026/0343823 A1
(43) Pub. Date: Oct. 29, 2026

(54) THERMAL CONDUCTION ASSEMBLY AND ELECTRONIC DEVICE

(71) Applicant: WNC Corporation, Hsinchu (TW)

(72) Inventors: Ming Ying KUO, Hsinchu (TW); Ming Tsung WANG, Hsinchu (TW); Ching Hsun MENG, Hsinchu (TW)

(21) Appl. No.: 19/562,982

(22) Filed: Mar. 11, 2026

(30) Foreign Application Priority Data
Apr. 29, 2025 (TW) 114116098

(51) Int. Cl. H05K 7/20

(52) U.S. Cl. CPC H05K 7/20481; H05K 7/20418; H05K 7/20454; H05K 7/2049

(57) ABSTRACT

A thermal conduction assembly includes a thermal conduction pad and an elastic bracket unit. The elastic bracket unit includes at least one elastic portion and a receiving portion. The elastic portion is configured to provide a deformation of the elastic bracket unit, and the receiving portion is connected to the thermal conduction pad. At least one of the thermal conduction pad and the receiving portion is configured to be connected to an element requiring heat dissipation.

### RELATED APPLICATIONS

This application claims the benefit of priority to Taiwan Patent Application No. 114116098, filed on April 29, 2025. The entire content of the above identified application is incorporated herein by reference.

### BACKGROUND

### Technical Field

The present disclosure relates to a thermal conduction assembly and an electronic device, in particular to a thermal conduction assembly and an electronic device including a thermal conduction pad.

### DESCRIPTION OF RELATED ART

With continuous technological advances, the processing speed of electronic devices and the transmission speed of network communication connectors have been increasing. Accordingly, electronic devices and their network communication connectors require heat-dissipation structures or thermal conduction assemblies to address thermal issues. However, prior-art thermal conduction assemblies often fail to satisfy the high heat-dissipation demands under high processing/high transmission speeds, and often cannot achieve efficient heat exchange due to suboptimal structural design.

In view of the foregoing, there is an urgent need for thermal conduction assemblies and electronic devices that meet high processing/high transmission requirements and facilitate efficient heat exchange.

### SUMMARY

One aspect of the present disclosure is to provide a thermal conduction assembly including a thermal conduction pad and an elastic bracket unit. The elastic bracket unit includes at least one elastic portion and a receiving portion. The at least one elastic portion is configured to provide a deformation of the elastic bracket unit, and the receiving portion is connected to the thermal conduction pad. At least one of the thermal conduction pad and the receiving portion is configured to be connected to an element requiring heat dissipation.

Another aspect of the present disclosure is to provide a thermal conduction assembly including a plurality of thermal conduction pads and an elastic bracket unit. The elastic bracket unit includes at least one elastic portion and a plurality of receiving portions. The at least one elastic portion is configured to provide a deformation of the elastic bracket unit, and the receiving portions are respectively connected to the plurality of thermal conduction pads along a first direction. At least one of the plurality of thermal conduction pads and the plurality of receiving portions is configured to be connected to at least one element requiring heat dissipation.

Yet another aspect of the present disclosure is to provide an electronic device including an element requiring heat dissipation and a thermal conduction assembly. The thermal conduction assembly includes a thermal conduction pad and an elastic bracket unit. The elastic bracket unit includes at least one elastic portion and a receiving portion. The elastic portion is configured to provide a deformation of the elastic bracket unit, and the receiving portion is connected to the thermal conduction pad. At least one of the thermal conduction pad and the receiving portion is connected to the element requiring heat dissipation along a first direction.

### BRIEF DESCRIPTION OF THE DRAWINGS

The present disclosure can be more fully understood by reading the following detailed description of the embodiment, with reference made to the accompanying drawings as follows:

FIG. 1A is a three-dimensional view of a thermal conduction assembly of a first embodiment of the disclosure.

FIG. 1B is an exploded view of the thermal conduction assembly in FIG. 1A.

FIG. 1C is another exploded view of the thermal conduction assembly in FIG. 1A.

FIG. 1D is a sectional view of the thermal conduction assembly in FIG. 1A taken along line 1D-1D in FIG. 1C.

FIG. 2A is an exploded view of a thermal conduction assembly of a second embodiment.

FIG. 2B is a sectional view of the thermal conduction assembly after assembling taken along line 2B-2B in FIG. 2A.

FIG. 2C is another exploded view of the thermal conduction assembly in FIG. 2A.

FIG. 3A is an exploded view of a thermal conduction assembly of a third embodiment.

FIG. 3B is a sectional view of the thermal conduction assembly after assembling taken along line 3B-3B in FIG. 3A.

FIG. 4A is an exploded view of a thermal conduction assembly of a fourth embodiment.

FIG. 4B is a sectional view of the thermal conduction assembly after assembling taken along line 4B-4B in FIG. 4A.

FIG. 5 is a schematic view of a thermal conduction assembly of a fifth embodiment.

FIG. 6A is a schematic view of a thermal conduction assembly of a sixth embodiment.

FIG. 6B is another schematic view of the thermal conduction assembly in FIG. 6A.

FIG. 7 is an exploded view of a thermal conduction assembly of a seventh embodiment.

FIG. 8 is a three-dimensional view of an electronic device of an eighth embodiment.

### DETAILED DESCRIPTION

The present disclosure is more particularly described in the following embodiments that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an” and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

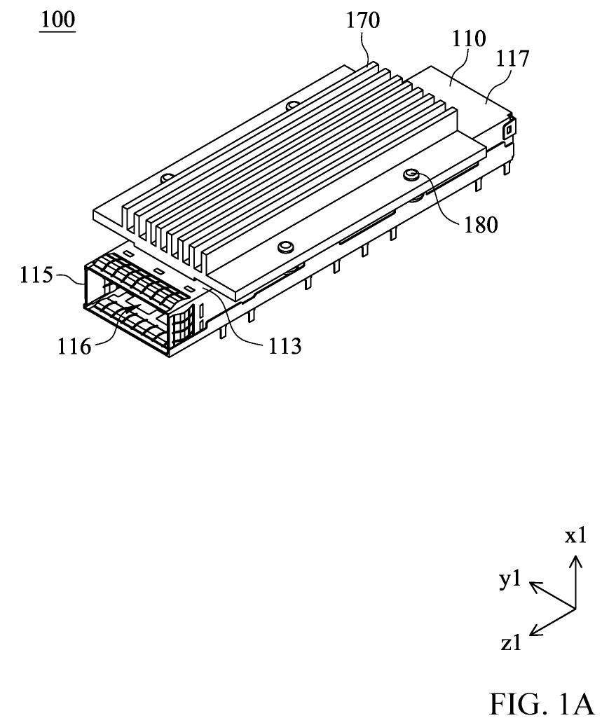

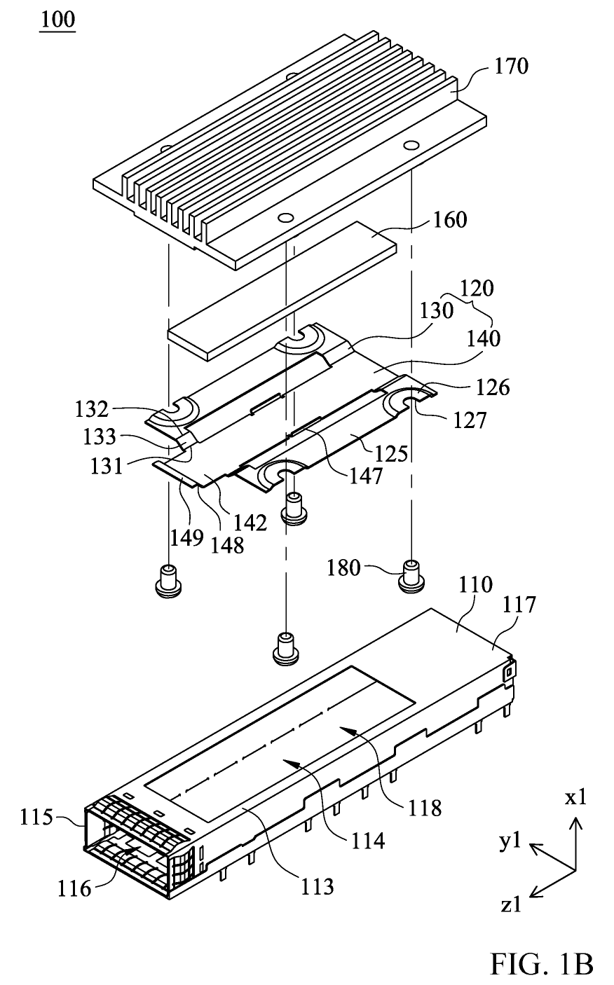

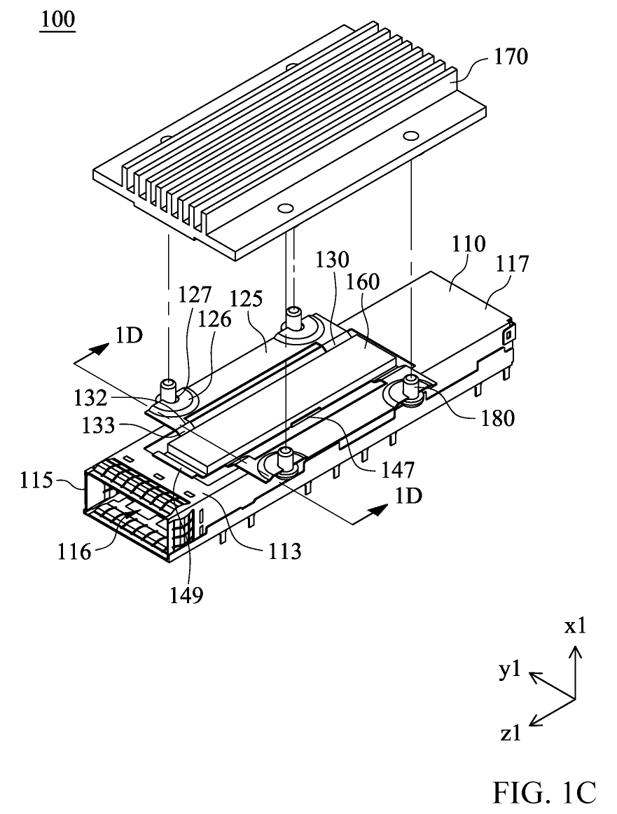

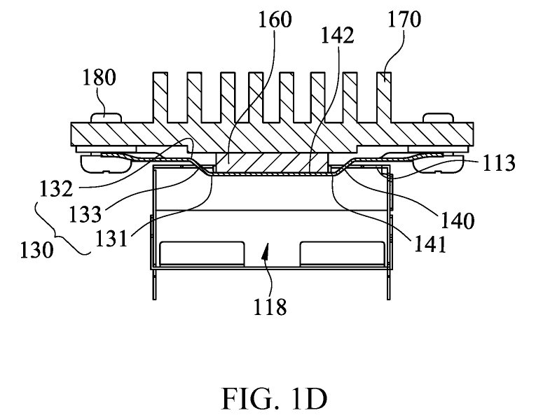

FIG. 1A is a three-dimensional view of a thermal conduction assembly 100 of a first embodiment of the disclosure. FIG. 1B is an exploded view of the thermal conduction assembly 100 in FIG. 1A. FIG. 1C is another exploded view of the thermal conduction assembly 100 in FIG. 1A. FIG. 1D is a sectional view of the thermal conduction assembly 100 in FIG. 1A taken along line 1D-1D in FIG. 1C. Referring to FIGS. 1A-1D, the thermal conduction assembly (heat dissipation assembly) 100 defines mutually orthogonal first direction x1, second direction y1, and third direction z1, and includes a thermal conduction pad 160 and an elastic bracket unit 120. The elastic bracket unit 120 includes at least one elastic portion 130 and a receiving portion 140. The elastic portion 130 provides deformation of the elastic bracket unit 120, and the receiving portion 140 is connected to the thermal conduction pad 160 and is thermally conductive. At least one of the thermal conduction pad 160 and the receiving portion 140 is configured to be connected to an element requiring heat dissipation (e.g., an element 880 requiring heat dissipation in FIG. 8). In the first embodiment, the receiving portion 140 directly connects to the element requiring heat dissipation, and the thermal conduction pad 160 indirectly connects to the element requiring heat dissipation. Accordingly, the thermal conduction assembly 100 helps improve the heat conduction efficiency of the element requiring heat dissipation and increases the design flexibility of the thermal conduction structure, and can be applied to miniaturized elements with high processing/high transmission speed. Furthermore, the elastic bracket unit 120 is made of aluminum or iron material (not limited thereto). The elastic bracket unit 120, which includes the elastic portion 130 and the receiving portion 140, is integrally formed, i.e., the elastic bracket unit 120 integrates both elastic and heat dissipation functions, which helps reduce the overall structural thickness of the thermal conduction assembly 100, thereby meeting product thickness requirements.

Specifically, the thermal conduction pad 160 may be made of an elastic material containing/including metal powder. Accordingly, the thermal conduction pad 160 is compressible, which helps absorb overall assembly tolerances of the thermal conduction assembly 100. Specifically, the thermal conduction pad 160 is formed of a silicone material mixed with metal powder, but is not limited thereto.

The thermal conduction assembly 100 may further include a cage element 110 connected to the elastic bracket unit 120. The cage element 110 includes a cage body 117, an accommodating space 118, and a first cage opening 114. The accommodating space 118 is formed in the cage body 117, and the first cage opening 114 is formed in a first surface portion 113 of the cage body 117. The accommodating space 118 is configured to accommodate the element requiring heat dissipation, and the receiving portion 140 passes through the first cage opening 114 to directly contact the element requiring heat dissipation. Thus, when the thermal conduction assembly 100 is used for dissipating heat of the element requiring heat dissipation in the cage element 110, the elastic bracket unit 120 provides an elastic limiting function. Compared with prior-art limiting elements lacking elasticity (such as the cage element itself or a circuit board), the thermal conduction assembly 100 of the disclosure enhances flexibility in positional and dimensional design.

The element requiring heat dissipation may be a pluggable module (pluggable element), without limitation. The cage element 110 may further include a second cage opening 116 formed in a second surface portion 115 of the cage body 117. The second cage opening 116 allows the element requiring heat dissipation to be inserted into and withdrawn from the cage element 110. Accordingly, the thermal conduction assembly 100 can provide a thermal conduction path for a pluggable module. Specifically, the pluggable module may be a small form-factor pluggable (SFP) module with network communication functionality. Specifically, the normal direction of the first surface portion 113 of the cage body 117 is parallel to the first direction x1, and the normal direction of the second surface portion 115 is parallel to the third direction z1.

The receiving portion 140 may include a contact surface 141 and a receiving surface 142, with the receiving surface 142 disposed opposite the contact surface 141. The contact surface 141 is configured to contact the element requiring heat dissipation, and the receiving surface 142 is connected to the thermal conduction pad 160. Accordingly, in addition to providing elasticity, the elastic bracket unit 120 also serves as an internal heat sink of the thermal conduction assembly 100 through its receiving portion 140, helping reduce the overall thickness of the elastic bracket unit 120 to meet product thickness requirements.

The thermal conduction pad 160 and the receiving portion 140 may be stacked along the first direction x1. The elastic portion 130 includes a first region 131, a second region 132, and a transition region 133 connected between the first region 131 and the second region 132. The first region 131 and the second region 132 correspond to different positions along the first direction x1. Thus, the elastic portion 130 of the elastic bracket unit 120 provides a spring-plate function: when the pluggable module is inserted into or withdrawn from the cage element 110, it applies sufficient downward pressure along the first direction x1 to ensure that the elastic bracket unit 120 of the thermal conduction assembly 100 fits tightly against the pluggable module, thereby enhancing heat dissipation. In addition, the receiving portion 140 may include at least one positioning structure 147, a chamfer structure 148, and a limiting structure 149. The positioning structure 147 positions the thermal conduction pad 160, the chamfer structure 148 serves as an insertion guide for the pluggable module, and the limiting structure 149 confines the mechanism at the first cage opening 114.

The thermal conduction assembly 100 may further include a second heat dissipation element 170 connected to the thermal conduction pad 160. Accordingly, the second heat dissipation element 170 may serve as an external heat sink to further enhance heat dissipation. The second heat dissipation element 170 may be a fin-type heat sink (as shown in FIGS. 1A-1D) or a cold plate. The fin-type heat sink may be made of aluminum or copper, and the cold plate may be made of aluminum, copper, or stainless steel, without limitation. Furthermore, in the prior art, different cage elements with corresponding heat dissipation solutions were required depending on dissipation conditions. By adopting the thermal conduction assembly 100 of the disclosure, only a cage element with a riding heat sink is needed, and the appropriate second heat dissipation elements 170 can be selected according to dissipation conditions. This reduces the variety of cage elements, thereby reducing part numbers and lowering costs.

Specifically, the thermal conduction path of the thermal conduction assembly 100 is sequentially formed/connected by the element requiring heat dissipation, the receiving portion 140, the thermal conduction pad 160, and the second heat dissipation element 170.

In addition, the thermal conduction assembly 100 further includes screws 180. On opposite sides of the elastic bracket unit 120 along the second direction y1 are two wing-shaped structures 125. Each wing-shaped structure 125 includes at least one boss 126 and at least one locking point 127. The bosses 126 provide locking strength for the elastic bracket unit 120. Through the screws 180, the locking points 127 of the elastic bracket unit 120 can be locked or positioned with the second heat dissipation element 170, the cage element 110, and/or the electronic device (such as the electronic device 800 in FIG. 8) in which the thermal conduction assembly 100 is installed. In certain embodiments (not shown) of the disclosure, any portion of the elastic bracket unit, the cage element, and the second heat dissipation element may be designed with positioning posts to provide alignment thereamong.

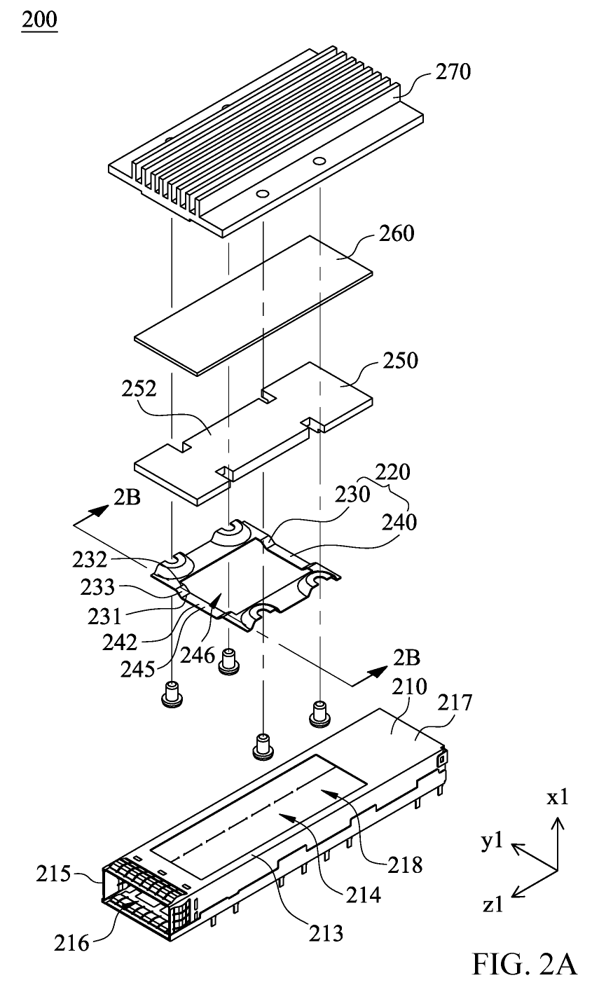

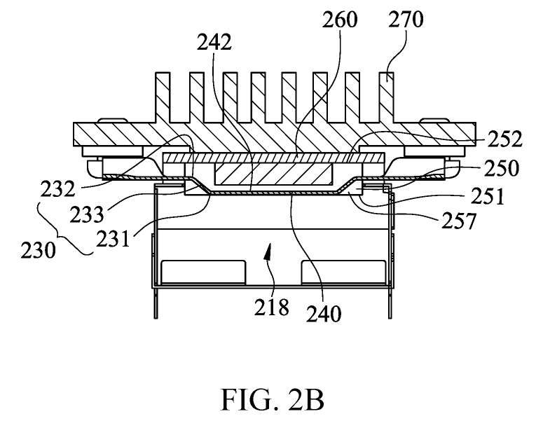

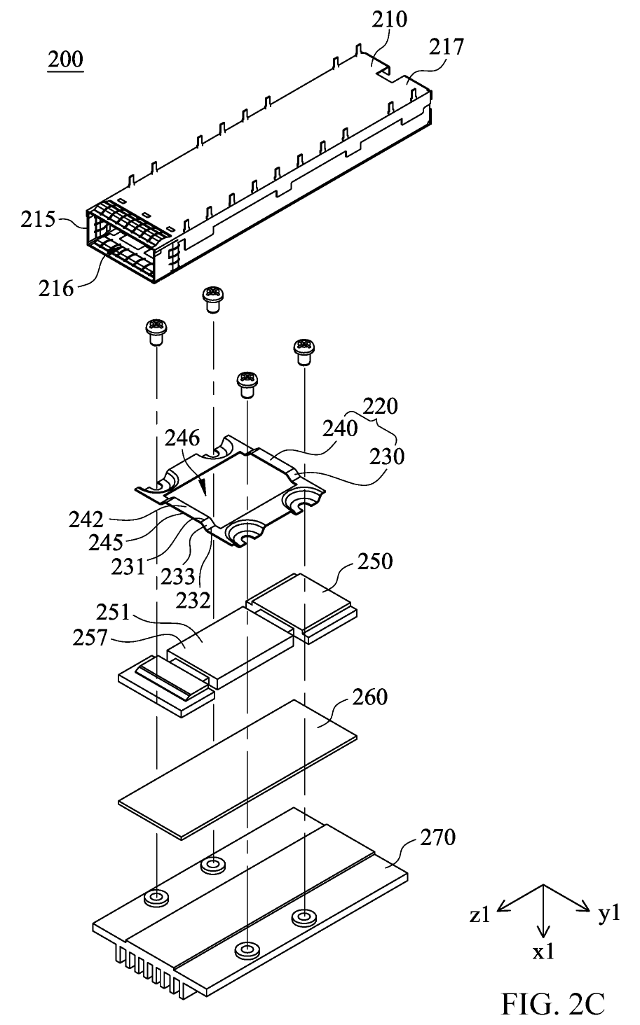

FIG. 2A is an exploded view of a thermal conduction assembly 200 of a second embodiment of the disclosure. FIG. 2B is a sectional view of the thermal conduction assembly 200 after assembling taken along line 2B-2B in FIG. 2A. FIG. 2C is another exploded view of the thermal conduction assembly 200 in FIG. 2A. Referring to FIGS. 2A-2C, the thermal conduction assembly 200 defines mutually orthogonal first direction x1, second direction y2, and third direction z1, and includes a thermal conduction pad 260 and an elastic bracket unit 220. The elastic bracket unit 220 includes at least one elastic portion 230 and a receiving portion 240. The elastic portion 230 provides deformation of the elastic bracket unit 220, and the receiving portion 240 is indirectly connected to the thermal conduction pad 260 and is thermally conductive. In the second embodiment, the thermal conduction pad 260 is used to indirectly connect to the element requiring heat dissipation.

Specifically, the thermal conduction assembly 200 further includes a cage element 210 connected to the elastic bracket unit 220. The cage element 210 includes a cage body 217, an accommodating space 218, and a first cage opening 214. The accommodating space 218 is formed in the cage body 217, and the first cage opening 214 is formed in a first surface portion 213 of the cage body 217. The accommodating space 218 accommodates the element requiring heat dissipation, and the thermal conduction pad 260 is configured to indirectly contact the element requiring heat dissipation through the first cage opening 214. The element requiring heat dissipation is a pluggable module. The cage element 210 further includes a second cage opening 216 formed in a second surface portion 215 of the cage body 217, and the element requiring heat dissipation can be inserted into and withdrawn from the cage element 210 through the second cage opening 216.

The thermal conduction pad 260 is made of an elastic material containing metal powder. The thermal conduction pad 260 and the receiving portion 240 are stacked along the first direction x1. The elastic portion 230 includes a first region 231, a second region 232, and a transition region 233 connected between the first region 231 and the second region 232. The first region 231 and the second region 232 correspond to different positions along the first direction x1.

The thermal conduction assembly 200 further includes a first heat dissipation element 250 connected to the thermal conduction pad 260. Thus, the thermal conduction assembly 200 can provide a thermal conduction path for the pluggable module. The elastic bracket unit 220 can apply downward pressure along the first direction x1, enabling the first heat dissipation element 250 of the thermal conduction assembly 200 to fit tightly with the pluggable module, thereby improving heat dissipation. Furthermore, the elastic bracket unit 220 may serve to position the first heat dissipation element 250. The first heat dissipation element 250 may be made of aluminum or copper, without limitation.

The receiving portion 240 includes a receiving body 245 and a receiving opening 246. The receiving body 245 surrounds and forms/defines the receiving opening 246, and the receiving body 245 receives either the thermal conduction pad 260 or the first heat dissipation element 250. In the second embodiment, the receiving body 245 directly receives the first heat dissipation element 250. The first heat dissipation element 250 is configured to contact the element requiring heat dissipation through the receiving opening 246. Thus, this arrangement allows for selection of the appropriate first heat dissipation element 250 according to different heat dissipation conditions, thereby reducing the design complexity of heat dissipation structures corresponding to different elements requiring heat dissipation.

The first heat dissipation element 250 includes a protrusion 257 that passes through the receiving opening 246 to contact the element requiring heat dissipation. Accordingly, when the element requiring heat dissipation is inserted into the cage element 210, the elastic portion 230 applies downward pressure along the first direction x1, ensuring that the protrusion 257 fits tightly against the pluggable module, thereby improving heat dissipation.

The first heat dissipation element 250 includes a first heat dissipation surface 251 and a second heat dissipation surface 252, with the second heat dissipation surface 252 disposed opposite the first heat dissipation surface 251. The first heat dissipation surface 251 is configured to contact the element requiring heat dissipation, and the second heat dissipation surface 252 is connected to the thermal conduction pad 260. Thus, the first heat dissipation element 250 and the thermal conduction pad 260 cooperate to satisfy the required heat dissipation conditions and meet the requirements of miniaturized structures.

The thermal conduction assembly 200 may further include a second heat dissipation element 270, with the thermal conduction pad 260 connected between the first heat dissipation element 250 and the second heat dissipation element 270. Thus, the second heat dissipation element 270 can serve as an external heat sink to further enhance heat dissipation. In addition, the thickness of the receiving portion 240, or the combined thickness (height) of the receiving portion 240 and the elastic portion 230, can be designed according to requirements. Reducing thickness lowers the thermal resistance along the conduction path to improve efficiency. The increasing thickness of the receiving portion 240, or the increasing combined thickness of the receiving portion 240 and the elastic portion 230 may accommodate installation requirements when the second heat dissipation element 270 requires a certain height.

Specifically, the thermal conduction path of the thermal conduction assembly 200 is sequentially formed by the element requiring heat dissipation, the first heat dissipation element 250, the thermal conduction pad 260, and the second heat dissipation element 270.

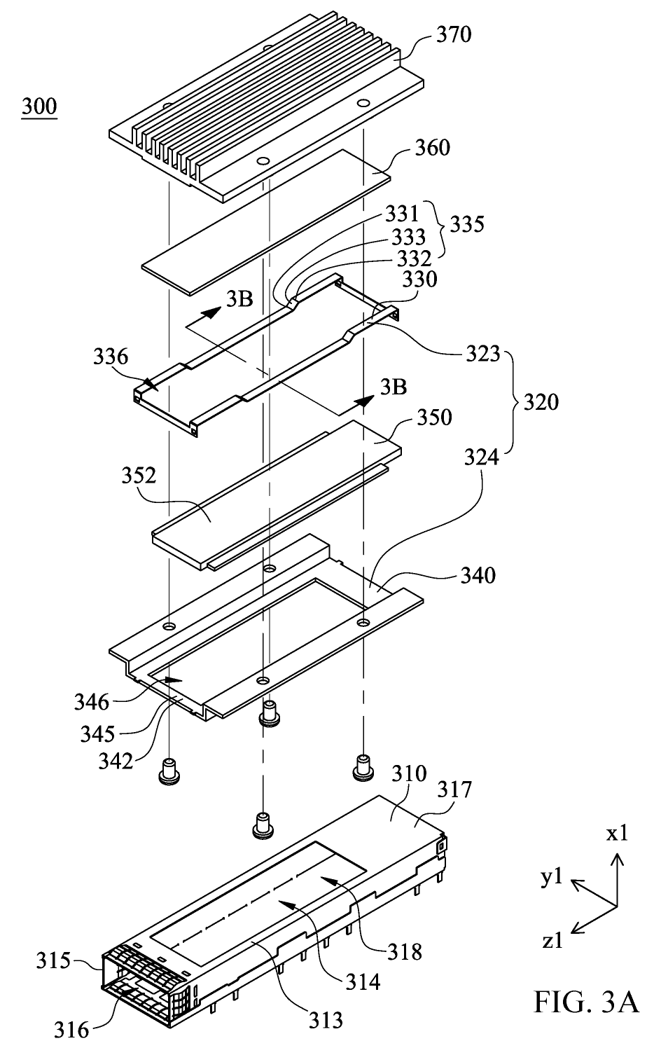

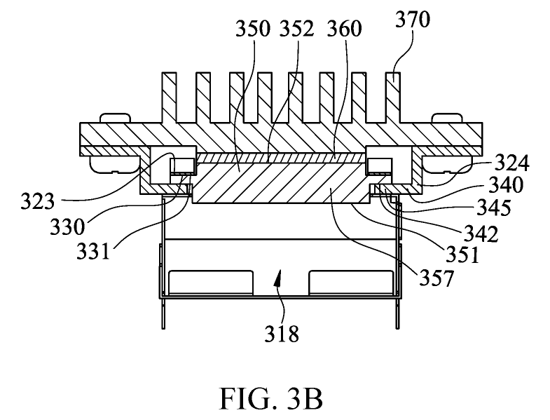

FIG. 3A is an exploded view of a thermal conduction assembly 300 of a third embodiment of the disclosure. FIG. 3B is a sectional view of the thermal conduction assembly 300 after assembling taken along line 3B-3B in FIG. 3A. Referring to FIGS. 3A and 3B, the thermal conduction assembly 300 defines mutually orthogonal first direction x1, second direction y1, and third direction z1, and includes a thermal conduction pad 360 and an elastic bracket unit 320. The elastic bracket unit 320 includes at least one elastic portion 330 and a receiving portion 340. The elastic portion 330 provides deformation of the elastic bracket unit 320, and the receiving portion 340 is indirectly connected to the thermal conduction pad 360 and is thermally conductive. In the third embodiment, the thermal conduction pad 360 indirectly connects to the element requiring heat dissipation.

Specifically, the thermal conduction assembly 300 further includes a cage element 310 connected to the elastic bracket unit 320. The cage element 310 includes a cage body 317, an accommodating space 318, and a first cage opening 314. The accommodating space 318 is formed in the cage body 317, and the first cage opening 314 is formed in a first surface portion 313 of the cage body 317. The accommodating space 318 accommodates the element requiring heat dissipation, and the thermal conduction pad 360 is configured to indirectly contact the element requiring heat dissipation through the first cage opening 314. The element requiring heat dissipation is a pluggable module. The cage element 310 further includes a second cage opening 316 formed in a second surface portion 315 of the cage body 317 and allowing the pluggable module to be inserted into and withdrawn from the cage element 310.

The thermal conduction assembly 300 further includes a first heat dissipation element 350 connected to the thermal conduction pad 360. The elastic bracket unit 320 further includes at least one elastic member 323 and a receiving member 324. The elastic member 323 and the receiving member 324 may be directly or indirectly connected, and are assembled into the elastic bracket unit 320 by riveting, snap-fit, or screw fastening (without limitation). The elastic member 323 includes the elastic portion 330, and the receiving member 324 includes the receiving portion 340. Accordingly, the receiving member 324 can serve to position the first heat dissipation element 350.

The receiving member 324 is positioned closer to the element requiring heat dissipation than the elastic member 323 thereto, and the first heat dissipation element 350 is clamped between the receiving member 324 and the elastic member 323. Accordingly, this facilitates stable fitting of the first heat dissipation element 350 with the pluggable module.

The receiving portion 340 of the receiving member 324 includes a receiving body 345 and a receiving opening 346. The receiving body 345 surrounds and defines the receiving opening 346, and directly receives the first heat dissipation element 350. The first heat dissipation element 350 is configured to contact the element requiring heat dissipation through the receiving opening 346. The first heat dissipation element 350 includes a protrusion 357 that passes through the receiving opening 346 to contact the element requiring heat dissipation. The first heat dissipation element 350 further includes a first heat dissipation surface 351 and a second heat dissipation surface 352. The second heat dissipation surface 352 is disposed opposite the first heat dissipation surface 351. The first heat dissipation surface 351 is configured to contact the element requiring heat dissipation, and the second heat dissipation surface 352 is connected to the thermal conduction pad 360.

The elastic member 323 includes an elastic body 335 and at least one elastic opening 336. The elastic body 335 surrounds and defines the elastic opening 336, which corresponds to the receiving opening 346. The first heat dissipation surface 351 of the first heat dissipation element 350 is configured to contact the element requiring heat dissipation through the receiving opening 346, and the second heat dissipation surface 352 of the first heat dissipation element 350 connects to the thermal conduction pad 360 through the elastic opening 336. Thus, the thermal conduction assembly 300 can provide a thermal conduction path for the pluggable module. The elastic member 323 can apply downward pressure, enabling the first heat dissipation element 350 of the thermal conduction assembly 300 to fit tightly with the pluggable module, thereby enhancing heat dissipation.

The ratio of the area of the elastic opening 336 to the area of the receiving opening 346 may range between 0.2 and 1.3, where the area refers to the projection on the plane defined/formed by the second direction y1 and the third direction z1. Accordingly, while maintaining heat dissipation performance, the design complexity of the elastic member 323, the receiving member 324, and the first heat dissipation element 350 for different elements requiring heat dissipation can be simplified.

The thermal conduction pad 360 is made of an elastic material containing metal powder. The thermal conduction pad 360 and the receiving portion 340 are stacked along the first direction x1. The elastic portion 330 includes a first region 331, a second region 332, and a transition region 333 connected between the first region 331 and the second region 332. The first region 331 and the second region 332 correspond to different positions along the first direction x1. The thermal conduction assembly 300 further includes a second heat dissipation element 370, with the thermal conduction pad 360 connected between the first heat dissipation element 350 and the second heat dissipation element 370.

Specifically, the thermal conduction path of the thermal conduction assembly 300 is sequentially formed by the element requiring heat dissipation, the first heat dissipation element 350, the thermal conduction pad 360, and the second heat dissipation element 370.

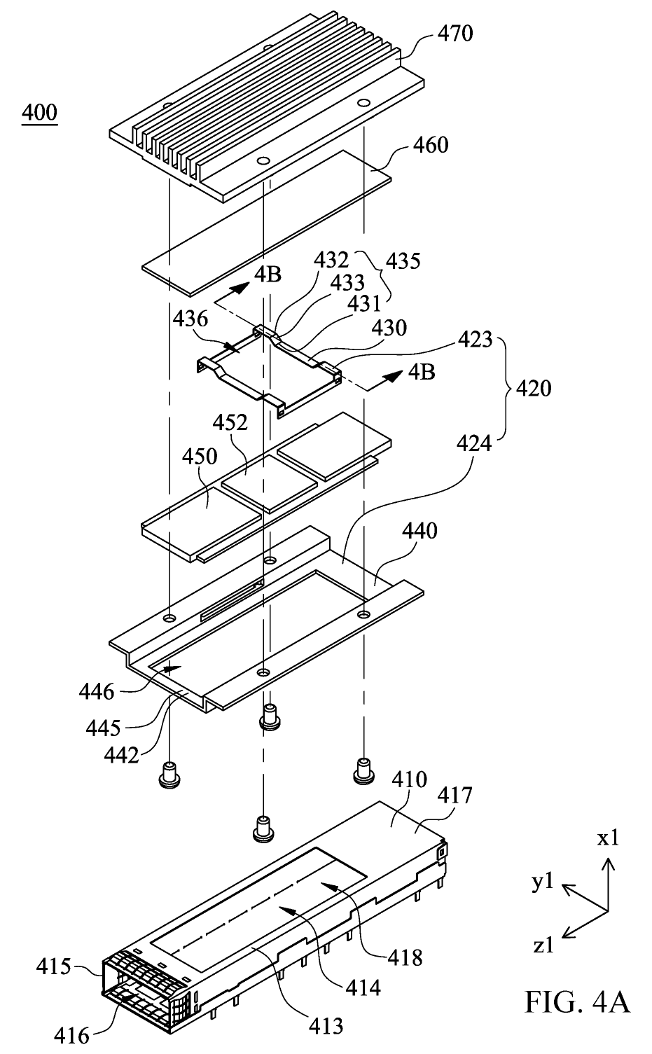

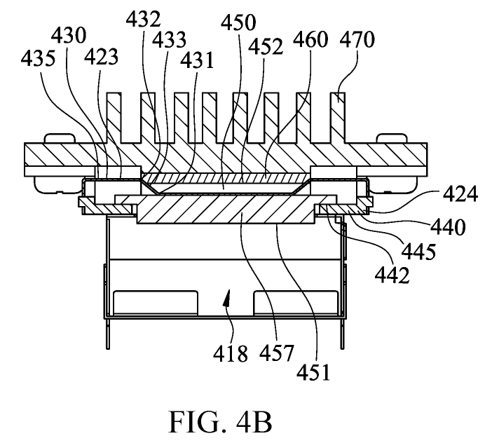

FIG. 4A is an exploded view of a thermal conduction assembly 400 of a fourth embodiment of the disclosure. FIG. 4B is a sectional view of the thermal conduction assembly 400 after assembling taken along line 4B-4B in FIG. 4A. Referring to FIGS. 4A and 4B, the thermal conduction assembly 400 defines mutually orthogonal first direction x1, second direction y1, and third direction z1, and includes a thermal conduction pad 460 and an elastic bracket unit 420. The elastic bracket unit 420 includes at least one elastic portion 430 and a receiving portion 440. The elastic portion 430 provides deformation of the elastic bracket unit 420, and the receiving portion 440 is indirectly connected to the thermal conduction pad 460 and is thermally conductive. In the fourth embodiment, the thermal conduction pad 460 is used to indirectly connect to the element requiring heat dissipation.

Specifically, the thermal conduction assembly 400 further includes a cage element 410 connected to the elastic bracket unit 420. The cage element 410 includes a cage body 417, an accommodating space 418, and a first cage opening 414. The accommodating space 418 is formed in the cage body 417, and the first cage opening 414 is formed in a first surface portion 413 of the cage body 417. The accommodating space 418 accommodates the element requiring heat dissipation, and the thermal conduction pad 460 is configured to indirectly contact the element requiring heat dissipation through the first cage opening 414. The element requiring heat dissipation is a pluggable module. The cage element 410 further includes a second cage opening 416 formed in a second surface portion 415 of the cage body 417, and the element requiring heat dissipation can be inserted into and withdrawn from the cage element 410 through the second cage opening 416.

The thermal conduction assembly 400 further includes a first heat dissipation element 450 connected to the thermal conduction pad 460. The elastic bracket unit 420 further includes at least one elastic member 423 and a receiving member 424. The elastic member 423 and the receiving member 424 may be directly or indirectly connected, and are assembled into the elastic bracket unit 420 by riveting, snap-fit, or screw fastening (without limitation). The elastic member 423 includes the elastic portion 430, and the receiving member 424 includes the receiving portion 440. The receiving member 424 is positioned closer to the element requiring heat dissipation than the elastic member 423 thereto, and the first heat dissipation element 450 is clamped between the receiving member 424 and the elastic member 423.

The receiving portion 440 of the receiving member 424 includes a receiving body 445 and a receiving opening 446. The receiving body 445 surrounds and defines the receiving opening 446, and directly receives the first heat dissipation element 450. The first heat dissipation element 450 is configured to contact the element requiring heat dissipation through the receiving opening 446. The first heat dissipation element 450 includes a protrusion 457 that passes through the receiving opening 446 to contact the element requiring heat dissipation. The first heat dissipation element 450 further includes a first heat dissipation surface 451 and a second heat dissipation surface 452. The second heat dissipation surface 452 is disposed opposite the first heat dissipation surface 451. The first heat dissipation surface 451 is configured to contact the element requiring heat dissipation, and the second heat dissipation surface 452 is connected to the thermal conduction pad 460.

The elastic member 423 includes an elastic body 435 and at least one elastic opening 436. The elastic body 435 surrounds and defines the elastic opening 436, which corresponds to the receiving opening 446. The first heat dissipation surface 451 of the first heat dissipation element 450 is configured to contact the element requiring heat dissipation through the receiving opening 446, and the second heat dissipation surface 452 of the first heat dissipation element 450 connects to the thermal conduction pad 460 through the elastic opening 436. The ratio of the area of the elastic opening 436 to the area of the receiving opening 446 may range between 0.2 and 1.3. In addition, in the fourth embodiment, the elastic member 423 can be regarded as the elastic member 323 of the third embodiment rotated by 90 degrees.

The thermal conduction pad 460 is made of an elastic material containing metal powder. The thermal conduction pad 460 and the receiving portion 440 are stacked along the first direction x1. The elastic portion 430 includes a first region 431, a second region 432, and a transition region 433 connected between the first region 431 and the second region 432. The first region 431 and the second region 432 correspond to different positions along the first direction x1. The thermal conduction assembly 400 further includes a second heat dissipation element 470, with the thermal conduction pad 460 connected between the first heat dissipation element 450 and the second heat dissipation element 470.

Specifically, the thermal conduction path of the thermal conduction assembly 400 is sequentially formed by the element requiring heat dissipation, the first heat dissipation element 450, the thermal conduction pad 460, and the second heat dissipation element 470.

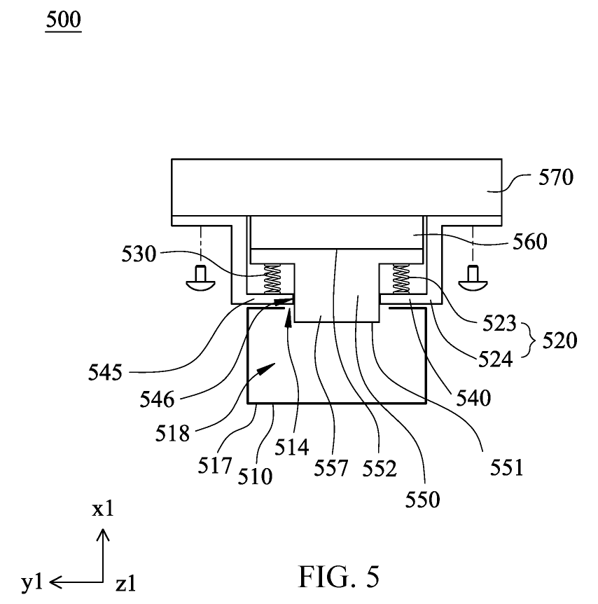

FIG. 5 is a schematic view of a thermal conduction assembly 500 of a fifth embodiment of the disclosure. Referring to FIG. 5, the thermal conduction assembly 500 defines mutually orthogonal first direction x1, second direction y1, and third direction z1, and includes a thermal conduction pad 560 and an elastic bracket unit 520. The elastic bracket unit 520 includes at least one elastic portion 530 and a receiving portion 540. The elastic portion 530 provides deformation of the elastic bracket unit 520, and the receiving portion 540 is indirectly connected to the thermal conduction pad 560 and is thermally conductive. In the fifth embodiment, the thermal conduction pad 560 indirectly connects to the element requiring heat dissipation.

Specifically, the thermal conduction assembly 500 further includes a cage element 510 connected to the elastic bracket unit 520. The cage element 510 includes a cage body 517, an accommodating space 518, and a first cage opening 514. The accommodating space 518 is formed in the cage body 517, and is configured to accommodate the element requiring heat dissipation. The thermal conduction pad 560 is configured to indirectly contact the element through the first cage opening 514. The element requiring heat dissipation is a pluggable module. The cage element 510 further includes a second cage opening (not shown), which allows the pluggable module to be inserted into and withdrawn from the cage element 510.

The thermal conduction assembly 500 further includes a first heat dissipation element 550 connected to the thermal conduction pad 560. The elastic bracket unit 520 further includes at least one elastic member 523 and a receiving member 524. The elastic member 523 and the receiving member 524 are assembled into the elastic bracket unit 520 by riveting, snap-fit, or screw fastening (without limitation). The elastic member 523 includes the elastic portion 530, and the receiving member 524 includes the receiving portion 540.

The elastic member 523 is at least one spring, with its two ends respectively connected to the receiving member 524 and the first heat dissipation element 550. The receiving member 524 includes a receiving opening 546. The first heat dissipation surface 551 of the first heat dissipation element 550 is configured to contact the element requiring heat dissipation through the receiving opening 546. Accordingly, this configuration satisfies broader and more stable elastic requirements.

The receiving portion 540 of the receiving member 524 further includes a receiving body 545 that surrounds and defines the receiving opening 546. The receiving body 545 specifically receives the first heat dissipation element 550 through the elastic member 523. The first heat dissipation element 550 is configured to contact the element requiring heat dissipation through the receiving opening 546. The first heat dissipation element 550 includes a protrusion 557 that passes through the receiving opening 546 to contact the element requiring heat dissipation. The first heat dissipation element 550 further includes a first heat dissipation surface 551 and a second heat dissipation surface 552. The second heat dissipation surface 552 is disposed opposite the first heat dissipation surface 551. The first heat dissipation surface 551 is configured to contact the element requiring heat dissipation, and the second heat dissipation surface 552 is connected to the thermal conduction pad 560.

The thermal conduction pad 560 is made of an elastic material containing metal powder. The thermal conduction assembly 500 further includes a second heat dissipation element 570, with the thermal conduction pad 560 connected between the first heat dissipation element 550 and the second heat dissipation element 570.

Specifically, the thermal conduction path of the thermal conduction assembly 500 is sequentially formed by the element requiring heat dissipation, the first heat dissipation element 550, the thermal conduction pad 560, and the second heat dissipation element 570.

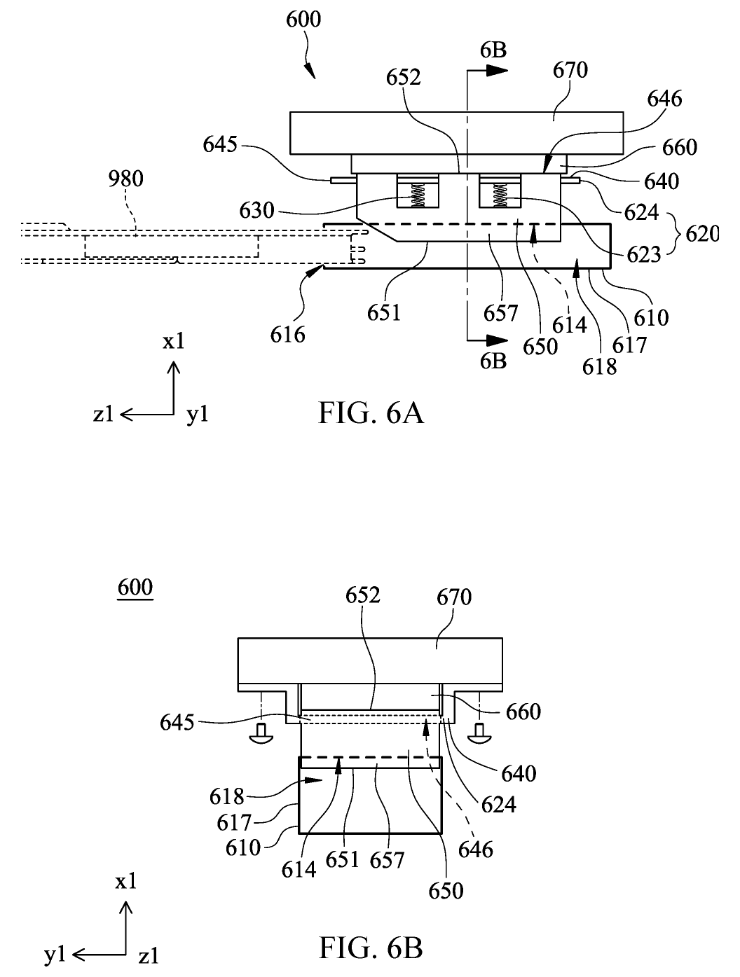

FIG. 6A is a schematic view of a thermal conduction assembly 600 of a sixth embodiment of the disclosure. FIG. 6B is another schematic view of the thermal conduction assembly 600 in FIG. 6A. Referring to FIGS. 6A and 6B, the thermal conduction assembly 600 defines mutually orthogonal first direction x1, second direction y1, and third direction z1, and includes a thermal conduction pad 660 and an elastic bracket unit 620. The elastic bracket unit 620 includes at least one elastic portion 630 and a receiving portion 640. The elastic portion 630 provides deformation of the elastic bracket unit 620, and the receiving portion 640 is indirectly connected to the thermal conduction pad 660 and is thermally conductive. In the sixth embodiment, the thermal conduction pad 660 is configured to indirectly connect to the element 980 requiring heat dissipation.

Specifically, the thermal conduction assembly 600 further includes a first heat dissipation element 650 connected to the thermal conduction pad 660. The thermal conduction assembly 600 further includes a cage element 610 connected to the elastic bracket unit 620. The cage element 610 includes a cage body 617, an accommodating space 618, and a first cage opening 614. The accommodating space 618 is formed in the cage body 617 and is configured to accommodate the element 980 requiring heat dissipation. The thermal conduction pad 660 is configured to indirectly contact the element 980 requiring heat dissipation through the first heat dissipation element 650 passing through the first cage opening 614. The element 980 requiring heat dissipation is a pluggable module. The cage element 610 further includes a second cage opening 616, through which the element 980 requiring heat dissipation can be inserted into and withdrawn from the cage element 610.

The elastic bracket unit 620 further includes at least one elastic member 623 and a receiving member 624. The elastic member 623 and the receiving member 624 are assembled into the elastic bracket unit 620 by riveting, snap-fit, or screw fastening (without limitation). The elastic member 623 includes the elastic portion 630, and the receiving member 624 includes the receiving portion 640.

The elastic member 623 is at least one spring, with its two ends respectively connected to the receiving member 624 and the first heat dissipation element 650. The receiving member 624 includes a receiving body 645 and a receiving opening 646. The receiving body 645 surrounds and defines the receiving opening 646, and the first heat dissipation element 650 passes through the receiving opening 646 to contact the thermal conduction pad 660.

The first heat dissipation element 650 includes a protrusion 657 that passes through the first cage opening 614 to contact the element 980 requiring heat dissipation. The first heat dissipation element 650 further includes a first heat dissipation surface 651 and a second heat dissipation surface 652. The second heat dissipation surface 652 is disposed opposite the first heat dissipation surface 651. The first heat dissipation surface 651 is configured to contact the element 980 requiring heat dissipation, and the second heat dissipation surface 652 is connected to the thermal conduction pad 660.

The thermal conduction pad 660 is made of an elastic material containing metal powder. The thermal conduction assembly 600 further includes a second heat dissipation element 670, with the thermal conduction pad 660 connected between the first heat dissipation element 650 and the second heat dissipation element 670.

Specifically, the thermal conduction path of the thermal conduction assembly 600 is sequentially formed by the element 980 requiring heat dissipation, the first heat dissipation element 650, the thermal conduction pad 660, and the second heat dissipation element 670.

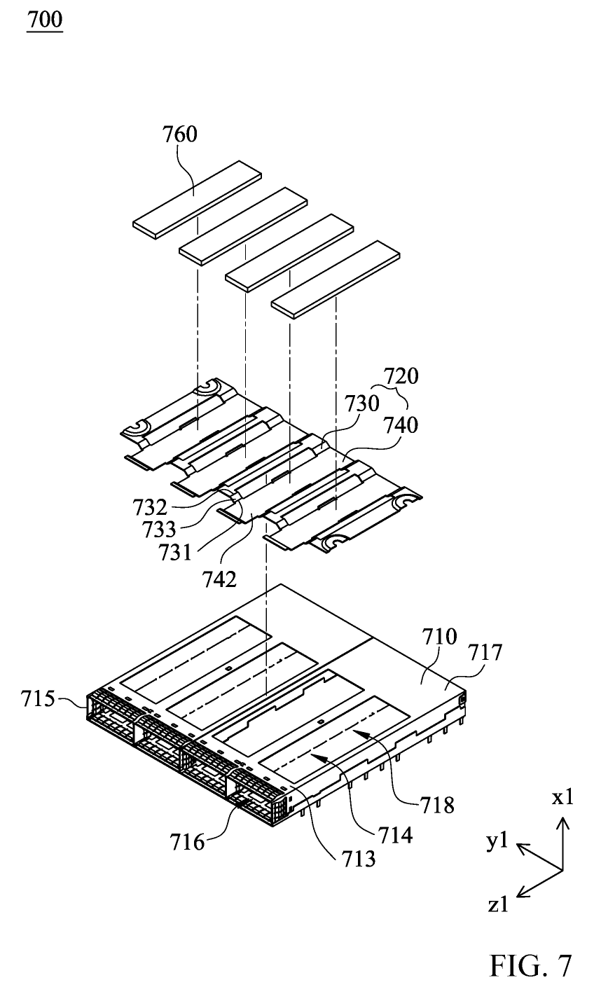

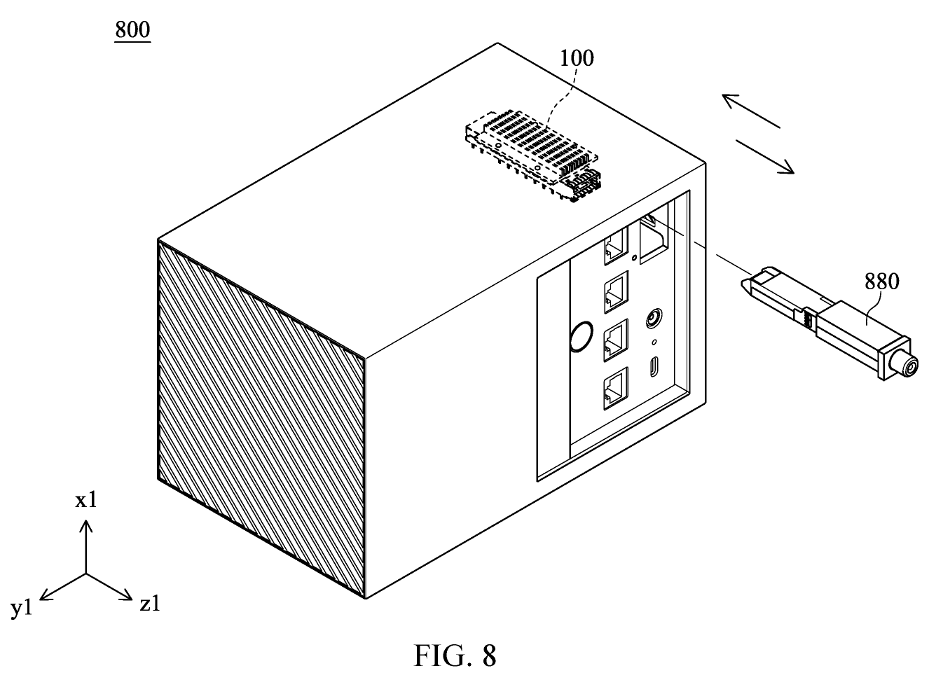

FIG. 7 is an exploded view of a thermal conduction assembly 700 of a seventh embodiment of the disclosure. Referring to FIG. 7, the thermal conduction assembly 700 defines mutually orthogonal first direction x1, second direction y1, and third direction z1, and includes a plurality of thermal conduction pads 760 and an elastic bracket unit 720. The elastic bracket unit 720 includes at least one elastic portion 730 and a plurality of receiving portions 740. The elastic portion 730 provides deformation of the elastic bracket unit 720, and the receiving portions 740 are respectively connected to the thermal conduction pads 760 along the first direction x1. At least one of the thermal conduction pads 760 and the receiving portions 740 is configured to be connected to at least one element requiring heat dissipation. Thus, the thermal conduction assembly 700 of the disclosure can be applied to one or multiple elements requiring heat dissipation, improving heat conduction efficiency and increasing the design flexibility of the thermal conduction structure, and can be applied to miniaturized elements requiring heat dissipation with high processing/high transmission speed. In the seventh embodiment, the number of receiving portions 740 is equal to the number of thermal conduction pads 760, wherein the receiving portions 740 are respectively used to directly connect the plurality of elements requiring heat dissipation, and the thermal conduction pads 760 are respectively used to indirectly connect the plurality of elements.

Specifically, the thermal conduction pads 760 are made of an elastic material containing metal powder. The thermal conduction assembly 700 further includes a cage element 710 connected to the elastic bracket unit 720. The cage element 710 includes a cage body 717, a plurality of accommodating spaces 718, and a plurality of first cage openings 714. Each accommodating space 718 is formed in the cage body 717, and each first cage opening 714 is formed in a first surface portion 713 of the cage body 717. The plurality of accommodating spaces 718 are configured to respectively accommodate the plurality of elements requiring heat dissipation, and the plurality of receiving portions 740 respectively pass through the plurality of first cage openings 714 to directly contact the plurality of elements requiring heat dissipation.

The element requiring heat dissipation may be a pluggable module. The cage element 710 may further include a plurality of second cage openings 716 formed in a second surface portion 715 of the cage body 717. The plurality of second cage openings 716 allow the plurality of elements requiring heat dissipation to be respectively inserted into and withdrawn from the cage element 710.

Each receiving portion 740 includes a contact surface and a receiving surface 742, with the receiving surface 742 disposed opposite the contact surface. Each contact surface is configured to contact an element requiring heat dissipation, and each receiving surface 742 is connected to the corresponding thermal conduction pad 760.

Each thermal conduction pad 760 and the corresponding receiving portion 740 are stacked along the first direction x1. Each elastic portion 730 includes a first region 731, a second region 732, and a transition region 733 connected between the first region 731 and the second region 732. The first region 731 and the second region 732 correspond to different positions along the first direction x1.

The number of elastic portions 730 is plural, and the elastic portions 730 and the receiving portions 740 are alternately arranged along the second direction y1. Thus, since the thermal conduction structure (such as the plurality of thermal conduction pads 760) and the positioning structure (such as the elastic bracket unit 720) are not integrated into a single component, the thermal conduction assembly 700 of the disclosure can reduce mutual influence among different mechanisms while maintaining independent heat conduction performance. Furthermore, when the thermal conduction assembly 700 is used for dissipating heat from the plurality of elements requiring heat dissipation in the cage element 710, the plurality of elastic portions 730 and the plurality of receiving portions 740 of the elastic bracket unit 720 are alternately connected along the second direction y1. The elastic bracket unit 720 may provide individual and independent spring mechanisms for each pluggable module, helping reduce mutual influence among different mechanisms while maintaining independent heat dissipation performance. For example, when only a middle one of the accommodating spaces 718 receives a pluggable module, the independent structural design of the thermal conduction assembly 700 prevents protrusion in the middle along the first direction x1 caused by applied force.

Specifically, the thermal conduction path for an element requiring heat dissipation connected to the thermal conduction assembly 700 is sequentially formed by the element requiring heat dissipation, the receiving portion 740, and the thermal conduction pad 760.

FIG. 8 is a three-dimensional view of an electronic device 800 of an eighth embodiment of the disclosure. Referring to FIG. 8, the electronic device 800 may be a router and includes an element 880 requiring heat dissipation and a thermal conduction assembly according to the disclosure, such as the thermal conduction assembly 100 of the first embodiment. The thermal conduction assembly 100 includes the thermal conduction pad 160 and the elastic bracket unit 120. The elastic bracket unit 120 includes at the least one elastic portion 130 and the receiving portion 140. The elastic portion 130 provides deformation of the elastic bracket unit 120, and the receiving portion 140 is directly connected to the thermal conduction pad 160. The receiving portion 140 is connected to the element 880 requiring heat dissipation along the first direction x1. Thus, the thermal conduction assembly 100 helps improve the heat conduction efficiency of the element 880 requiring heat dissipation and increases the design flexibility of the thermal conduction structure, and can be applied to miniaturized elements requiring heat dissipation with high processing/high transmission speed.

Specifically, the element 880 requiring heat dissipation is a pluggable module, and the element 880 is inserted into and withdrawn from the electronic device 800 along the third direction z1. Thus, the thermal conduction assembly 100 can provide a thermal conduction path for the pluggable module while achieving both high heat conduction efficiency and miniaturization characteristics.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A thermal conduction assembly, comprising:
a thermal conduction pad; and
an elastic bracket unit comprising at least one elastic portion and a receiving portion, wherein the at least one elastic portion is configured to provide a deformation of the elastic bracket unit, and the receiving portion is connected to the thermal conduction pad;
wherein at least one of the thermal conduction pad and the receiving portion is configured to be connected to an element requiring heat dissipation.

2. The thermal conduction assembly according to claim 1, wherein the thermal conduction pad is made of an elastic material comprising a metal powder.

3. The thermal conduction assembly according to claim 1, further comprising:
a cage element connected to the elastic bracket unit, the cage element comprising a cage body, an accommodating space, and a first cage opening, wherein the accommodating space is formed in the cage body, and the first cage opening is formed in a first surface portion of the cage body;
wherein the accommodating space is configured to accommodate the element requiring heat dissipation, and at least one of the thermal conduction pad and the receiving portion is configured to connect to the element requiring heat dissipation through the first cage opening.

4. The thermal conduction assembly according to claim 3, wherein the element requiring heat dissipation is a pluggable module, and the cage element further comprises a second cage opening formed in a second surface portion of the cage body, the second cage opening being configured to allow the pluggable module to be inserted into and withdrawn from the cage element.

5. The thermal conduction assembly according to claim 1, wherein the receiving portion comprises a contact surface and a receiving surface, the receiving surface being disposed opposite the contact surface, the contact surface being configured to contact the element requiring heat dissipation, and the receiving surface being connected to the thermal conduction pad.

6. The thermal conduction assembly according to claim 1, wherein the thermal conduction pad and the receiving portion are stacked along a first direction, and the elastic portion comprises a first region, a second region, and a transition region connected between the first region and the second region, the first region and the second region respectively corresponding to different positions along the first direction.

7. The thermal conduction assembly according to claim 1, further comprising:
a first heat dissipation element connected to the thermal conduction pad.

8. The thermal conduction assembly according to claim 7, wherein the receiving portion comprises a receiving body and a receiving opening, the receiving body surrounding the receiving opening, the receiving body receiving one of the thermal conduction pad and the first heat dissipation element, and the one of the thermal conduction pad and the first heat dissipation element being configured to contact the element requiring heat dissipation through the receiving opening.

9. The thermal conduction assembly according to claim 8, wherein the one of the thermal conduction pad and the first heat dissipation element comprises a protrusion, the protrusion passing through the receiving opening to contact the element requiring heat dissipation.

10. The thermal conduction assembly according to claim 7, wherein the first heat dissipation element comprises a first heat dissipation surface and a second heat dissipation surface, the second heat dissipation surface being disposed opposite the first heat dissipation surface, the first heat dissipation surface being configured to contact the element requiring heat dissipation, and the second heat dissipation surface being connected to the thermal conduction pad.

11. The thermal conduction assembly according to claim 10, further comprising:
a second heat dissipation element, wherein the thermal conduction pad is connected between the first heat dissipation element and the second heat dissipation element.

12. The thermal conduction assembly according to claim 10, wherein the elastic bracket unit further comprises at least one elastic member and a receiving member, the at least one elastic member and the receiving member being assembled to form the elastic bracket unit, the at least one elastic member comprising the at least one elastic portion, and the receiving member comprising the receiving portion.

13. The thermal conduction assembly according to claim 12, wherein the receiving member is configured to be positioned closer to the element requiring heat dissipation than the at least one elastic member thereto, and the first heat dissipation element is clamped between the receiving member and the at least one elastic member.

14. The thermal conduction assembly according to claim 12, wherein the receiving member comprises a receiving opening, and the at least one elastic member comprises at least one elastic opening corresponding to the receiving opening, the first heat dissipation surface of the first heat dissipation element being configured to contact the element requiring heat dissipation through the receiving opening, and the second heat dissipation surface of the first heat dissipation element being connected to the thermal conduction pad through the at least one elastic opening.

15. The thermal conduction assembly according to claim 14, wherein a ratio of an area of the at least one elastic opening to an area of the receiving opening ranges between 0.2 and 1.3.

16. The thermal conduction assembly according to claim 12, wherein the at least one elastic member is at least one spring, and two ends of the at least one elastic member are respectively connected to the receiving member and the first heat dissipation element;
wherein the receiving member comprises a receiving opening, and the first heat dissipation element is configured to contact the element requiring heat dissipation or the thermal conduction pad through the receiving opening.

17. A thermal conduction assembly, comprising:
a plurality of thermal conduction pads; and
an elastic bracket unit comprising at least one elastic portion and a plurality of receiving portions, wherein the at least one elastic portion is configured to provide a deformation of the elastic bracket unit, and the receiving portions are respectively connected to the plurality of thermal conduction pads along a first direction;
wherein at least one of the plurality of thermal conduction pads and the plurality of receiving portions is configured to be connected to at least one element requiring heat dissipation.

18. The thermal conduction assembly according to claim 17, wherein a number of the at least one elastic portion is plural, and the plurality of elastic portions and the plurality of receiving portions are alternately arranged along a second direction, the first direction and the second direction being perpendicular to each other.

19. An electronic device, comprising:
an element requiring heat dissipation; and
a thermal conduction assembly, comprising:
a thermal conduction pad; and
an elastic bracket unit comprising at least one elastic portion and a receiving portion, wherein the at least one elastic portion is configured to provide a deformation of the elastic bracket unit, and the receiving portion is connected to the thermal conduction pad;
wherein at least one of the thermal conduction pad and the receiving portion is connected to the element requiring heat dissipation along a first direction.

20. The electronic device according to claim 19, wherein the element requiring heat dissipation is a pluggable module, and the element requiring heat dissipation is inserted into and withdrawn from the electronic device along a third direction.
